(19) United States
(12) Patent Application Publication
(10) Pub. No.: US 2006/0170044 A1
(43) Pub. Date: Aug. 3, 2006

(54) One-transistor random access memory technology integrated with silicon-on-insulator process

(75) Inventor: Kuo-Chi Tu, Hsinchu (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/046,999

(22) Filed: Jan. 31, 2005

(51) Int. Cl. H01L 27/12; H01L 27/01; H01L 31/0392

(52) U.S. Cl. 257/347

(57) ABSTRACT

An one-transistor random access memory device integrated on a silicon-on-insulator (SOI) substrate has a capacitor structure buried in at least part of a capacitor trench in the SOI substrate, and a gate structure formed on the SOI substrate. A top electrode the capacitor structure is formed simultaneously with and of the same conductive material as a gate electrode of the gate structure. A capacitor dielectric layer of the capacitor structure is formed simultaneously with and of the same dielectric material as a gate dielectric layer of the gate structure.

### FIELD OF THE INVENTION

The present invention relates to a one-transistor random access memory (IT-RAM) technology, and particularly to a IT-RAM device with a buried capacitor fabricated on a silicon-on-insulator (SOI) substrate and a method of forming the same by integrating a IT-RAM process and a SOI process.

### BACKGROUND OF THE INVENTION

Typical memory cells are created comprising one single Metal-Oxide-Semiconductor Field-Effect-Transistor (MOS-FET) as a switching device connected with a capacitor as a digital data storage device, thus commonly referred to as a one-transistor random access memory (1T-RAM) device. The storage capacitor must have a minimum capacitance for reliably storing the charge and, at the same time, for enabling differentiation between the information that has been read. In more recent applications, the 1T-RAM cell is fabricated using a buried capacitor structure in part of a trench, requiring less space than stacked type capacitor structures.

FIG. 1 is a cross-sectional diagram illustrating a conventional 1T-RAM device with a buried capacitor. A silicon bulk substrate 10 has a memory cell array region where gate structures 12, source/drain regions 26 and a capacitor 14 are fabricated. The capacitor 14 comprised of a top electrode 20, a bottom electrode 22 and a capacitor dielectric layer 24, is substantially buried in part of a trench 16. The lower portion of the trench 16 is filled with silicon oxide, forming a shallow trench isolation (STI) structure 18. The upper portion of the trench 16 is filled with a polysilicon layer, forming the top electrode 20. The bottom electrode 22 is a doped silicon region formed by introducing impurity ions into silicon along the sidewalls of the upper portion of the trench 16; The capacitor dielectric layer 24 sandwiched between the top electrode 20 and the bottom electrode 22 is deposited along the sidewalls of the trench 16. One source/drain region 26 is electrically connected to the bottom electrode 22 via a connecting impurity diffusion region, and the other source/drain region 26 is connected to a bit line 30 via a contact hole 28 filled with a conductor. The conventional 1T-RAM cell, however, has disadvantages of low speed, high power consumption and insufficient capacitance. In addition, improvements in latch-up, soft-error and data retention time are needed in the conventional 1T-RAM cell to meet high performance of mobile computing system applications. U.S. Pat. No. 6,420,226 to Chen et al, describing a method of defining a buried stacked capacitor, is incorporated herein by reference. U.S. Pat. No. 6,661,049 to Tzeng et al, describing a microelectronic capacitor embedded within an isolation region, is incorporated herein by reference.

Recently, demand has been increasing for system-on-a-chip (SoC), in which a memory device and a logic core device are integrated in a single chip in order to improve system performance. On the other hand, silicon-on-insulator (SOI) devices-using an SOI substrate in place of a conventional silicon bulk substrate has been attracting a great deal of attention, and such SOI devices have already been mass-produced for use in high-performance logic circuits. SOI is the key technology to intrinsically realize both low-power and high-speed characteristics, especially thin-film SOI structure for DRAM. Takahisa Eimori, et al., “Approaches to Extra Low Voltage DRAM Operation by SOI-DRAM”, IEEE TRANSACTIONS ON ELECTRON DEVICES, VOL. 45, NO. 5, MAY 1998 pp. 1000 to 1009, is incorporated herein by reference. None of the cited reference teaches a method to form, nor a structure having, a 1T-RAM device with a buried capacitor on a SOI substrate to bring small junction capacitance and reduced paths of leakage current. Such a method and structure are disclosed in embodiments of this disclosure.

### SUMMARY OF THE INVENTION

These and other problems are generally solved or circumvented, and technical advantages are generally achieved, by preferred embodiments of the present invention that utilize an one-transistor random access memory process integrated with a silicon-on-insulator (SOI) process. Such the SOI-based 1T-RAM device brings advantages of high-speed operation, low-power consumption and moderate capacitance, improves soft-error and latch-up immunity, and contributes to a long static retention time.

In preferred embodiments, an one-transistor random access memory device integrated on a silicon-on-insulator (SOI) substrate has a capacitor structure buried in at least part of a capacitor trench in the SOI substrate, and agate structure formed on the SOI substrate. A top electrode of the capacitor structure is formed simultaneously with and of the same conductive material as a gate electrode of the gate structure. A capacitor dielectric layer of the capacitor structure is formed simultaneously with and of the same dielectric material as a gate dielectric layer of the gate structure.

In preferred embodiments, the top electrode and the gate electrode are formed of a polysilicon layer, and the capacitor dielectric layer and the gatedielectric layer are formed of a dielectric layer with a dielectric constant less than about 4.0 In preferred embodiments, the top electrode and the gate electrode are formed of a metal layer, and the capacitor dielectric layer and the gate dielectric layer are formed of a dielectric layer with a dielectric constant greater than about 4.0.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIG. 1 is a cross-sectional diagram illustrating a conventional 1T-RAM device with a buried capacitor; and

FIGS. 2-7 are cross-section diagrams illustrating an exemplary embodiment of a 1T-RAM process integrated with a SOI process according to the present invention.

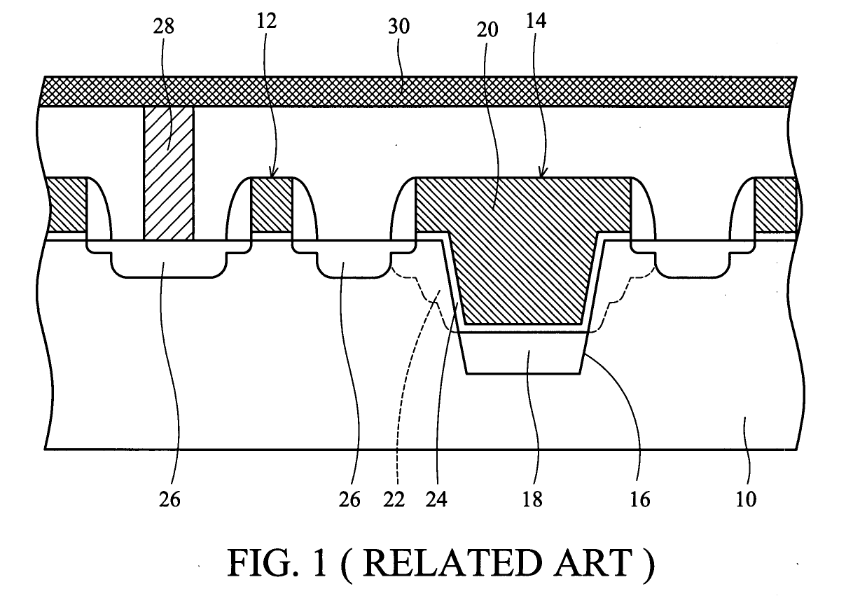

### DESCRIPTION OF THE PREFERRED EMBODIMENTS

The present invention provides a 1T-RAM technology integrated with a SOI process, referred to as a SOI-based 1T-RAM process, to form a 1T-RAM device on a SOI substrate, which overcomes the problems of the prior art arising from the use of silicon bulk substrate. Such the SOI-based 1T-RAM device brings advantages of high-speed operation, low-power consumption and moderate capacitance, improves soft-error and latch-up immunity, and contributes to a long static retention time. The SOI-based 1T-RAM process has wide applicability to many manufacturers, factories and industries and is potentially suited to a wide range of semiconductor device applications, for example mixed-mode integrated circuits, radio frequency (RF) circuits, static random access memory (SRAM), and dynamic random access memory (DRAM) technologies. The SOI-based 1T-RAM device may be built in a system-on-chip (SOC) including memory cell (e.g., DRAM, SRAM, Flash, EEPROM and EPROM), logic, analog and I/O devices. For an embedded 1T-RAM process, a SOI-based memory process of the present invention may be compatible with a SOI-based logic process or any other SOI-based process. In one embodiment of the invention, the SOI-based 1T-RAM process can fabricate a capacitor structure buried in at least part of a trench of a SOI substrate. One approach for improved capacitance is to increase the depth of the trench, and thereby the capacitor structure may extend to a deeper location of the SOI substrate.

Reference will now be made in detail to the present preferred embodiments of the invention, examples of which are illustrated in the accompanying drawings. Wherever possible, the same reference numbers are used in the drawings and the description to refer to the same or like parts. In the drawings, the shape and thickness of an embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be presented.

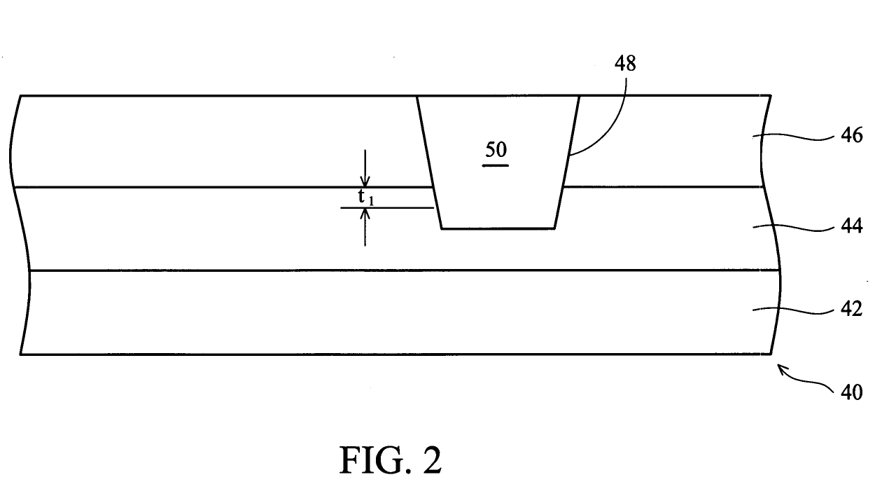

An active memory cell region where a buried capacitor structure incorporated into a 1T-RAM cell and a SOI substrate is fabricated will now be described in detail. Herein, cross-sectional diagrams of FIGS. 2-7 illustrate an exemplary embodiment of a 1T-RAM process integrated with a SOI process according to the present invention.

In FIG. 2, a SOI substrate 40 is provided with a predetermined capacitor region and at least one transistor region. The SOI substrate 40 comprises a first dielectric layer 44 interposed between a base substrate 42 and a semiconductor layer 46. The base substrate 42 may comprise silicon, gallium arsenide, gallium nitride, strained silicon, silicon germanium, silicon carbide, carbide, diamond, an epitaxy layer, and/or other materials. The semiconductor layer 46 may comprise silicon, gallium arsenide, gallium nitride, strained silicon, silicon germanium, silicon carbide, carbide, diamond, and/or other materials. The semiconductor layer 46 may have a thickness ranging between about 5 nm and about 400 nm in one embodiment. The first dielectric layer 44 may comprise silicon oxide, silicon nitride, silicon oxynitride, and/or other dielectric materials. The first dielectric layer 44 may have a thickness ranging from about 10 nm to about 200 nm. The first dielectric layer 44 and the semiconductor layer 46 may be formed using various SOI technologies. For example, the first dielectric layer 44 may be formed on a semiconductor wafer by a process referred to as separation by implanted oxygen (SIMOX). The SIMOX technology is based on ion-implanting a high-dose of oxygen ions into a silicon wafer, such that the peak concentration lies beneath the silicon surface. After implantation the wafer is subjected to a high-temperature anneal (about 1150° C. to about 1400° C., for example) to form a continuous stoichiometric subsurface layer of silicon dioxide. Thus formed first dielectric layer 44, also referred to as buried oxide or BOX electrically separates the semiconductor layer 46 and the base substrate 42.

After the SOI process, advances in lithography and masking techniques and dry etch processes, are employed to form a trench 48 in the SOI substrate 40 where a buried capacitor structure will be fabricated. The trench 48 may be created using a pad oxide layer and a pad nitride layer as the mask and using a reactive ion etching (RIE) process to reach a predetermined depth in the SOI substrate 40. Preferably, the trench 48 is etched into the semiconductor layer 46 and at least part of the first dielectric layer 44. For example, the trench 48 penetrates the first dielectric layer 44 to reach a depth (t₁) between 10 Angstroms to 500 Angstroms. The trench 48 is then filled with thermal oxide in one embodiment. The trench 48 may also be partially filled using thermal oxidation and then completely filled with silicon oxide using chemical vapor deposition (CVD) process in one embodiment. The oxide filled trench is then planarized using chemical mechanical polishing (CMP), for example. Other STI structures used for defining element-to-element active regions, may be fabricated simultaneously at this step, thereby simplifying the 1T-RAM process, while the insulating material of the STI structure 50 will be removed selectively from the capacitor region (e.g., the trench 48) in subsequent processes.

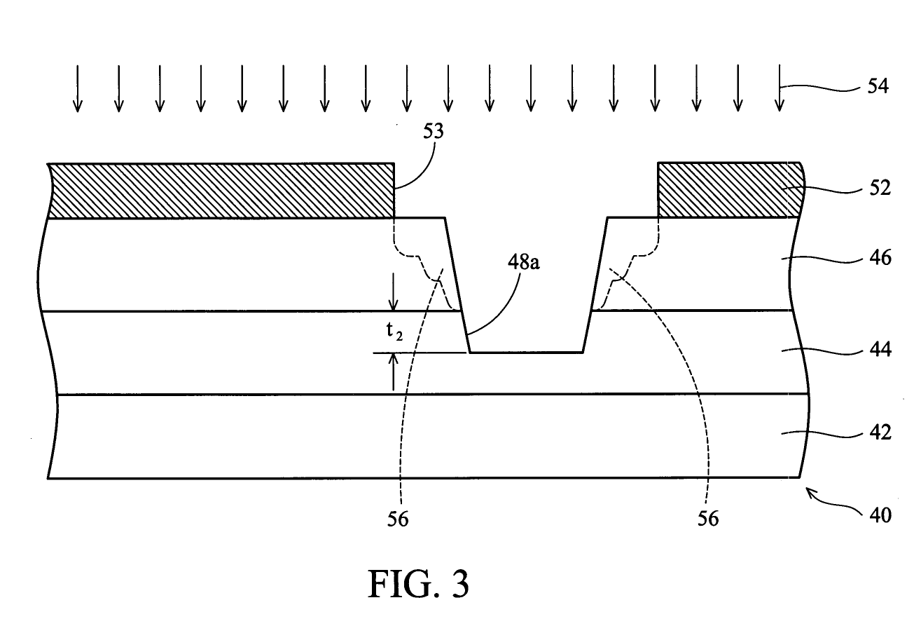

In FIG. 3, a photoresist layer 52 having a pattern opening 53 corresponding to a capacitor structure pattern is provided over the semiconductor layer 46, and the insulating material of the STI structure 50 is then removed from the trench 48 through the pattern opening 53 by the use of any well-known etching process, thus the trench 48 is exposed as a capacitor trench 48a. Sometimes, the step of patterning the capacitor region may be accomplished by main etch followed by over-etch, and therefore the exposed portion of the first dielectric layer 44 may be further recessed to reach a deeper location as compared with FIG. 2. For example, the capacitor trench 48a penetrates the first dielectric layer 44 to reach a depth (t₂) between 10 Angstroms to 500 Angstroms. For improved capacitance, the capacitor trench 48a may be recessed to reach a deeper location.

Following the formation of the capacitor trench 48a, first doped regions 56 are formed in the semiconductor layer 46 along the sidewalls and top portions of the capacitor trench 48a by introducing impurity ions into the exposed portions of the semiconductor layer 46, for example using an ion implantation process 54 with the photoresist layer 52 as a mask, thus a bottom electrode 56 of the capacitor structure is formed. If a P-channel MOSFET device is to be used as the transistor in the 1T-RAM cell, the first doped region 56 will be a heavily doped P type region, obtained via implantation of boron or BF₂ ions at an energy between about 3 to 10 Kev, and at a dose between about 1E14 to 1E16 atoms/cm². Alternatively, if the 1T-RAM cell is to be comprised with a N-channel MOSFET device, the first doped region 56 will be, achieved via implantation of arsenic or phosphorous ions, at an energy between about 10 to 50 KeV, and at a dose between about 1E14 to 1E16 atoms/cm².

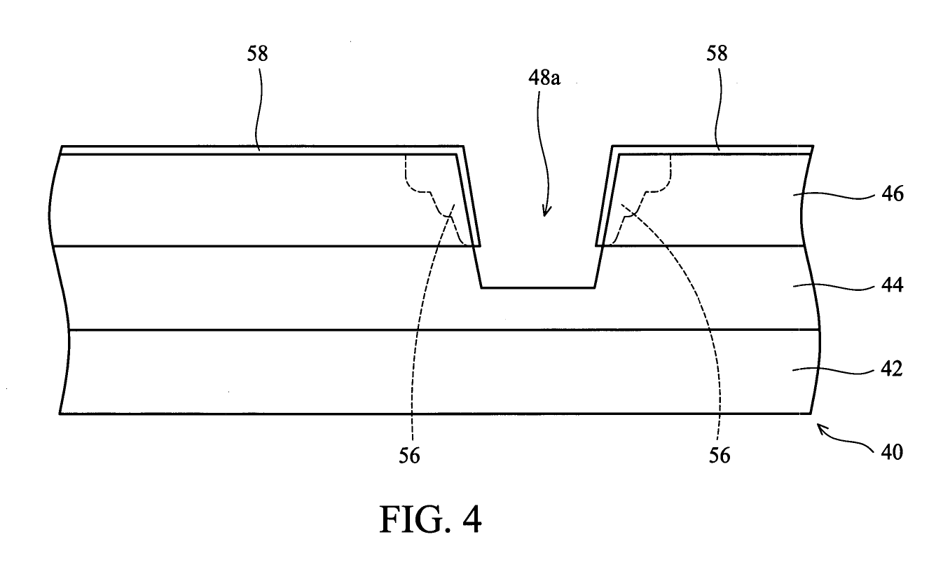

After stripping off the photoresist layer 52, a second dielectric layer 58 is conformally deposited on the semiconductor layer 46 through any of a variety of deposition techniques, including thermal oxidation, CVD, LPCVD, APCVD, PECVD, ALD and the like, as depicted in FIG. 4. Particularly, the second dielectric layer 58 which covers the first doped regions 56 will be patterned as a capacitor dielectric layer in subsequent processes, while the second dielectric layer 58 which covers areas corresponding to predetermined transistor patterns will be patterned as a gate dielectric layer in subsequent processes. Accordingly, the SOI-based 1T-RAM technology of the present invention allows a gate dielectric layer formed of the same dielectric material as a capacitor dielectric layer. In one embodiment, the second dielectric layer 58 is a silicon oxide layer formed by using thermal oxidation or CVD methods. In one embodiment, the second dielectric layer 58 may be an oxidized silicon nitride (NO) layer, or an oxidized silicon nitride layer on silicon oxide (ONO). In one embodiment, the second dielectric layer 58 comprises a high-k dielectric material that has a dielectric constant (k) greater than about 4.0, preferably from about 8 to about 50. It is noted that all the dielectric constants disclosed herein are relative to a vacuum, unless otherwise stated. A wide variety of high-k dielectrics may be employed including, but not limited to: binary metal oxides such as Ta₂O₅, HfO₂, Al₂O₃, InO₂, La₂O₃, ZrO₂ and TaO₂; silicates, aluminates and oxynitrides of said binary metal oxides; and perovskite-type oxides. Combinations and/or multilayers of such high-k dielectrics are also contemplated herein. The thickness of the second dielectric layer 58 is chosen specifically for the scaling requirements of the 1T-RAM device technology. Preferably, the second dielectric layer 58 has a thickness of from about 10 to about 250 angstroms.

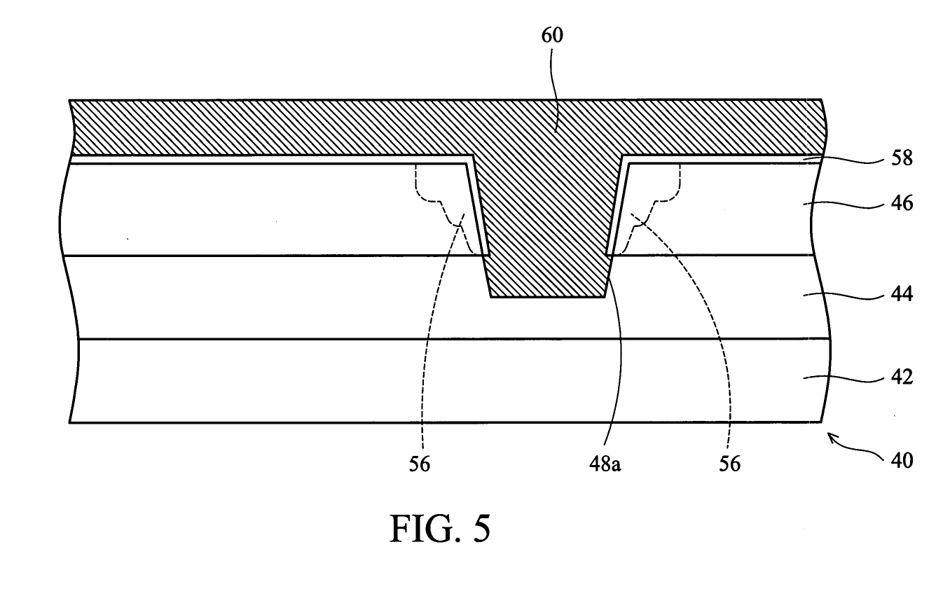

In FIG. 5, a first conductive layer 60 is deposited on the second dielectric layer 58 to fill the capacitor trench 48a completely. The first conductive layer 60 may be planarized using CMP or etch back processes if necessary. The first conductive layer 60 that fills the capacitor trench 48a and faces the first doped regions 56, will be defined as a top electrode of the capacitor structure in subsequent processes. The first conductive layer 60 that covers areas corresponding to predetermined transistor patterns, will be patterned as a gate electrode in subsequent processes. Accordingly, the SOI-based 1T-RAM technology of the present invention allows a gate electrode formed of the same conductive material as atop electrode of the capacitor structure. In one embodiment, when the second dielectric layer 58 is a silicon oxide layer, the first conductive layer 60 is adoped polysilicon layer formed by for example, depositing an intrinsic polysilicon material via LPCVD procedures followed by ion implantation. In one embodiment, when the second dielectric layer 58 is a high-k material layer, the conductive layer 60 maybe a single-metal layer, a dual-metal structure or a multi-layered structure selected from at least one of W, WNₓ, Ti, TiWₓ, TiNₓ, Ta, TaNₓ, Mo, Al, Cu, and the like. Any of a variety of deposition techniques, including, but not limited to, CVD, PVD, evaporation, plating, sputtering, reactive co-sputtering or combinations thereof may allow the production of the metal layer.

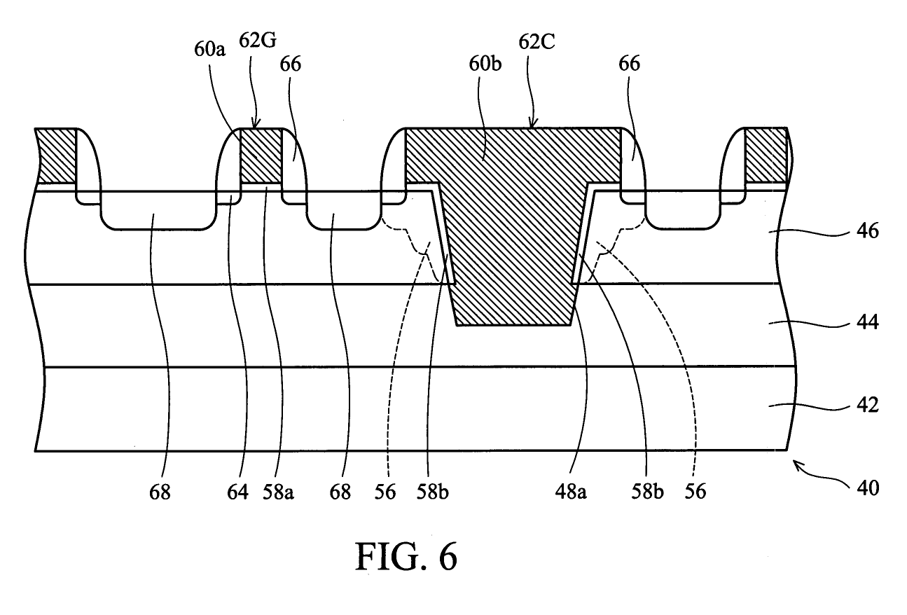

In FIG. 6, the first conductive layer 60 is defined as patterns of a gate electrode 60a and a top electrode 60b simultaneously through advances in lithography and masking techniques and dry etch processes (such as RIE and plasma etching). The underlying second dielectric layer 58 is then etched as patterns of a gatedielectric layer 58a and a capacitor dielectric layer 58b simultaneously by using a dry etching process with the gate electrode 60a and the top electrode 60b as the mask. Thus, at least one gate structure 62G including the gate electrode 60a stacked on the gate dielectric layer 58a, and at least one capacitor structure 62C including the capacitor dielectric layer 58b sandwiched between the top electrode 60b and the bottom electrode 56, are completed on the SOI substrate 40 simultaneously. Such capacitor structure 62C is buried in at least part of the capacitor trench 48a, and the top electrode 60 may extend downwardly to reach at least part of the first dielectric layer 44.

Following the formation of the gate structure 62G and the capacitor structure 62C, lightly doped drain (LDD) regions 64, dielectric spacers 66, and source/drain regions 68 are successively formed as depicted in FIG. 6 by the use of any well-known processes. For example, a lightly doped ion implantation process is performed with various dopant species into the semiconductor layer 46 to form the LDD regions 64. The margins of the LDD regions 64 are substantially aligned to the sidewall of the gate structure 62G and the exposed sidewall of the top electrode 60b. The lightly doped ion implantation process may be performed at energy between about 1 to about 100 KeV, at dosage of between about 1×1013 to about 1×1015 ions/cm₂. Advances in deposition, lithography, masking techniques and dry etch processes are followed to form the dielectric spacers 66 along the sidewalls of the gate structure 62G and the exposed sidewalls of the top electrode 60b. The dielectric spacers 66 may be formed of a silicon nitride layer, a silicon oxide layer, a silicon oxynitride layer, alternating layers of silicon oxide and silicon nitride, or combinations thereof. A heavily doped ion implantation process is then performed and the dielectric spacers 66 are used as the mask to implant various dopant species into the semiconductor layer 46, resulting in the source/drain regions 68. The margins of the source/drain regions 68 are substantially aligned to the exterior sidewalls of the dielectric spacers 66, respectively. One source/drain region 68 is electrically connected to the bottom electrode 56 via a connecting impurity diffusion region, and the other source/drain region 68 will be connected to a bit line in subsequent processes. The heavily doped ion implantation process may be performed at energy between about 1 to 100 KeV, at dosage between about 5×1013 to 1×1016 ions/cm². An optional metal silicide layer using a refractory metal such as cobalt, tungsten, titanium, nickel or the like may be formed on the surface of the gate electrode 60a and the surface of the source/drain regions 68 to lower their resistance values.

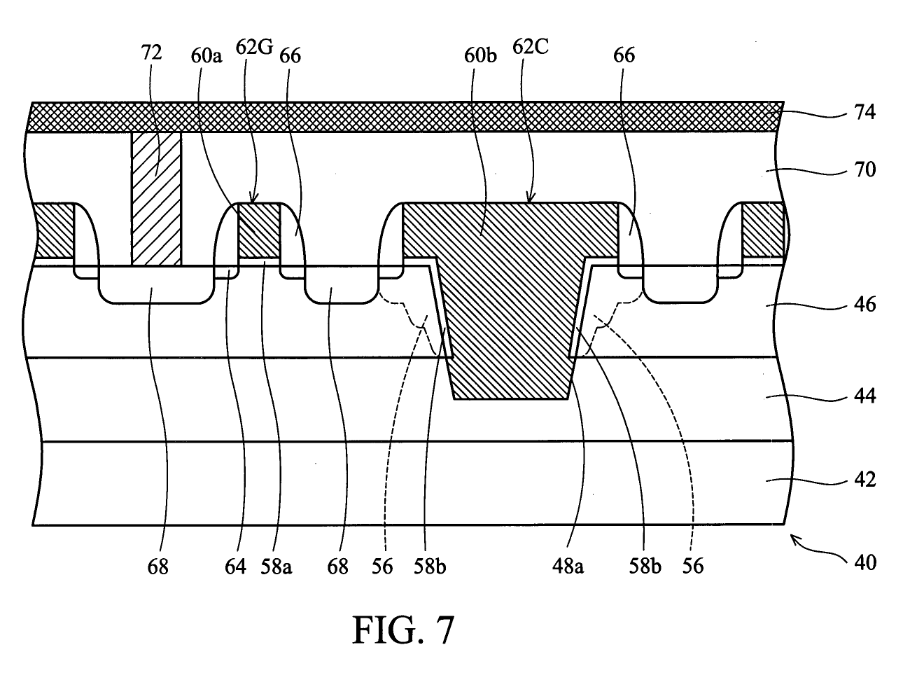

Once the source/drain regions 68 are completed immediately above, integrated processes for an interlayer dielectric (ILD) layer 70, a contact hole and a bit line 74 proceed on the SOI substrate 40 as depicted in FIG. 7. For example, an optional etch stop layer may be deposited followed by a deposition process for the ILD layer 70, and then a CMP process may be applied to planarize the ILD layer 70, if necessary. The ILD layer 70 may include, but not limited to, silicon dioxide, undoped silicate glass (USG), fluorinated silicate glass (FSG), and the like of low-k materials (e.g., dielectric constant value k<4.0). After the ILD formation, a typical lithographic and etch operation may be employed to form a contact hole 72 which penetrates the ILD layer 70 to expose one source/drain region 68 and will be filled with a conductive material for electrical connection to the source/drain region 68 and the bit line 74.

The SOI substrate, unlike a bulk silicon substrate, has a stacked structure including a base layer providing a supporting means, a buried oxide layer and a semiconductor layer. The 1T-RAM device integrated on such a SOI substrate 40 can be completely isolated from one another by the buried oxide layer. In addition, the SOI-based 1T-RAM device can reduce junction capacitance for reduced power consumption and increased operational speed. As the performance of semiconductor devices continues to improve, the range of applications for the SOI-based 1T-RAM device continues to expand. For example, the small junction capacitance reduces the bit line parasitic capacitance, thereby offering large read signal by the reduction of the bit line to memory cell capacitance ratio (CR). The small junction capacitance also contributes to the high-speed operation by the reduction CR time-constant of wiring. The simple and complete isolation improves soft-error and latch-up immunity. The reduced paths of leakage current contribute to the long static retention time and the low stand-by current.

Although the present invention and its advantages have been described in detail, it should be understood that various changes, substitutions and alterations may be made herein without departing from the spirit and scope of the invention as defined by the appended claims. For example, it will be readily understood by those skilled in the art that materials and methods may be varied while remaining within the scope of the present invention. For example, the present invention is not limited to silicon based ICs, but it is useful for compound semiconductor devices such as gallium arsenide as well.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device, comprising:
a silicon-on-insulator (SOI) substrate having a capacitor trench;
a capacitor structure buried in at least part of said capacitor trench, wherein said capacitor structure comprises a bottom electrode, a top electrode and a capacitor dielectric layer sandwiched between said bottom electrode layer and said top electrode layer; and
at least one gate structure formed on said SOI substrate, wherein said gate structure comprises a gate dielectric layer and a gate electrode formed overlying said gate dielectric layer;
wherein, said top electrode is formed of the same conductive material as said gate electrode, and said capacitor dielectric layer is formed of the same dielectric material as said gate dielectric layer.

2. The semiconductor device of claim 1, wherein said SOI substrate comprises:
a base substrate;
a buried dielectric layer overlying said base layer; and
a semiconductor layer overlying said buried dielectric layer;
wherein said capacitor trench penetrates said semiconductor layer and at least part of said buried dielectric layer.

3. The semiconductor device of claim 2, wherein said capacitor trench reaches a depth from about 10 Angstroms to about 500 Angstroms in said buried dielectric layer.

4. The semiconductor device of claim 2, wherein said bottom electrode is a doped region disposed in said semiconductor layer and surrounding at least part of a sidewall portion and a top portion of said capacitor trench.

5. The semiconductor device of claim 4, further comprising a pair of source/drain regions in said semiconductor layer laterally adjacent to sidewalls of said gate structure respectively, wherein one of said source/drain regions is electrically connected to said bottom electrode.

6. The semiconductor device of claim 4, wherein said capacitor dielectric layer is formed along at least part of the sidewall portion and the top portion of said capacitor trench.

7. The semiconductor device of claim 4, wherein said top electrode is a conductive material filling said capacitor trench.

8. The semiconductor device of claim 1, wherein said top electrode and said gate electrode are formed of a polysilicon layer.

9. The semiconductor device of claim 1, wherein said top electrode and said gate electrode are formed of a metal layer.

10. The semiconductor device of claim 1, wherein said capacitor dielectric layer and said gate dielectric layer are formed of a dielectric layer with a dielectric constant less than about 4.0.

11. The semiconductor device of claim 1, wherein said capacitor dielectric layer and said gate dielectric layer are formed of a dielectric layer with a dielectric constant greater than about 4.0.

12. A memory device, comprising:
a silicon-on-insulator (SOI) substrate comprising a base layer, a buried dielectric layer overlying said base layer, a semiconductor layer overlying said buried dielectric layer, and a capacitor trench penetrating said semiconductor layer and at least part of said buried dielectric layer;
a capacitor structure buried in at least part of said capacitor trench, wherein said capacitor structure comprises a doped region formed in said semiconductor layer and surrounding at least part of said capacitor trench, a capacitor dielectric layer formed along a sidewall of said capacitor trench, and a conductive layer filling said capacitor trench;
at least one gate structure formed on said SOI substrate, wherein said gate structure comprises a gate dielectric layer overlying said semiconductor layer, a gate electrode overlying said gate dielectric layer, and a pair of source/drain regions in said semiconductor layer laterally adjacent to sidewalls of said gate structure respectively;
wherein, said capacitor dielectric layer is formed simultaneously with and of the same dielectric material as said gate dielectric layer.

13. The memory device of claim 12, wherein said capacitor trench reaches a depth from about 10 Angstroms to about 500 Angstroms in said buried dielectric layer.

14. The memory device of claim 12, wherein said gate electrode is formed simultaneously with and of the same material as said conductive layer of said capacitor structure.

15. The memory device of claim 14, wherein said gate electrode and said conductive layer are formed of a polysilicon layer.

16. The memory device of claim 15, wherein said capacitor dielectric layer and said gate dielectric layer are formed of a dielectric layer with a dielectric constant less than about 4.0.

17. The memory device of claim 14, wherein said gate electrode and said conductive layer are formed of a metal layer.

18. The memory device of claim 17, wherein said capacitor dielectric layer and said gate dielectric layer are formed of a dielectric layer with a dielectric constant greater than about 4.0.

19. The memory device of claim 12, wherein one of said source/drain regions is electrically connected to said doped region of said capacitor structure.
